(19) United States
(12) Patent Application Publication
(10) Pub. No.: US 2008/0218972 A1
(43) Pub. Date: Sep. 11, 2008

(54) Cooling device, system containing same, and cooling method

(76) Inventors: Ioan Sauciuc, Phoenix, AZ (US); Seri Lee, Beaverton, OR (US); Alin Ila, Phoenix, AZ (US); Steven Girouard, Maricopa, AZ (US); Javier Leija, Chandler, AZ (US); Behre Mulugeta, Union City, CA (US)

Correspondence Address: INTEL CORPORATION;c/o INTELLEVATE, LLC, P.O. BOX 52050, MINNEAPOLIS, MN, 55402, US

(21) Appl. No.: 11/714,333

(22) Filed: Mar. 6, 2007

(51) Int. Cl. H05K 7/20; F28F 13/00

(52) U.S. Cl. 361/704; 165/185

(57) ABSTRACT

A cooling device includes a heat sink (110) having a plurality of fins (111) and a piezoelectric assembly (120) having an actuator (121) and a plurality of blades (122) coupled to the actuator. The actuator includes a plurality of metal electrodes (227) and a plurality of piezoelectric layers (228). The fins of the heat sink are intertwined with the blades of the piezoelectric assembly.

### FIELD OF THE INVENTION

The disclosed embodiments of the invention relate generally to cooling systems, and relate more particularly to piezoelectric cooling devices.

### BACKGROUND OF THE INVENTION

Computer chips and other microelectronic devices generate heat during their operation that, if not properly addressed, is capable of negatively affecting the performance of, or even damaging, the system of which the microelectronic device is a part. One technique for addressing such heat makes use of a heat sink in combination with a piezoelectric assembly having blades that vibrate or otherwise move to create airflow. However, existing cooling devices of this type require relatively high voltages and relatively long blades in order to achieve an effective blade vibration amplitude. Accordingly, there exists a need for a piezoelectric cooling device that does not share the problems that characterize the existing solutions.

### BRIEF DESCRIPTION OF THE DRAWINGS

The disclosed embodiments will be better understood from a reading of the following detailed description, taken in conjunction with the accompanying figures in the drawings in which:

FIG. 1 is a front elevational view of a cooling device according to an embodiment of the invention;

FIG. 2 is a side elevational view of a portion of the cooling device of FIG. 1;

FIG. 3 is a flowchart illustrating a cooling method according to an embodiment of the invention;

FIGS. 4 and 5 are side and top views, respectively, of a portion of the cooling device of FIG. 1 according to an embodiment of the invention;

FIG. 6 is a graph plotting peak-to-peak amplitude of an actuator prong as a function of input voltage for two piezoelectric assemblies including one piezoelectric assembly according to an embodiment of the invention; and

FIG. 7 is a schematic representation of a system including a cooling device according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a cooling device comprises a heat sink having a plurality of fins and a piezoelectric assembly comprising an actuator and a plurality of blades coupled to the actuator. The actuator comprises multiple piezoelectric layers sandwiched between metal electrodes. The fins of the heat sink are intertwined with the blades of the piezoelectric assembly. Because the piezoelectric assembly has a plurality of blades that resemble the prongs of a rake, the piezoelectric assembly may be referred to as a “rake piezoelectric assembly,” which in turn may be abbreviated as “rake piezo.”

The cooling device described in the preceding paragraph offers several advantages over existing cooling devices, including existing rake piezo cooling devices. For example, as compared to existing cooling devices, the cooling device according to embodiments of the present invention is capable of obtaining a given strain at a significantly reduced voltage (or achieving greatly increased performance at the same voltage), is capable of achieving much greater amplitudes, and may be constructed to have significantly reduced length.

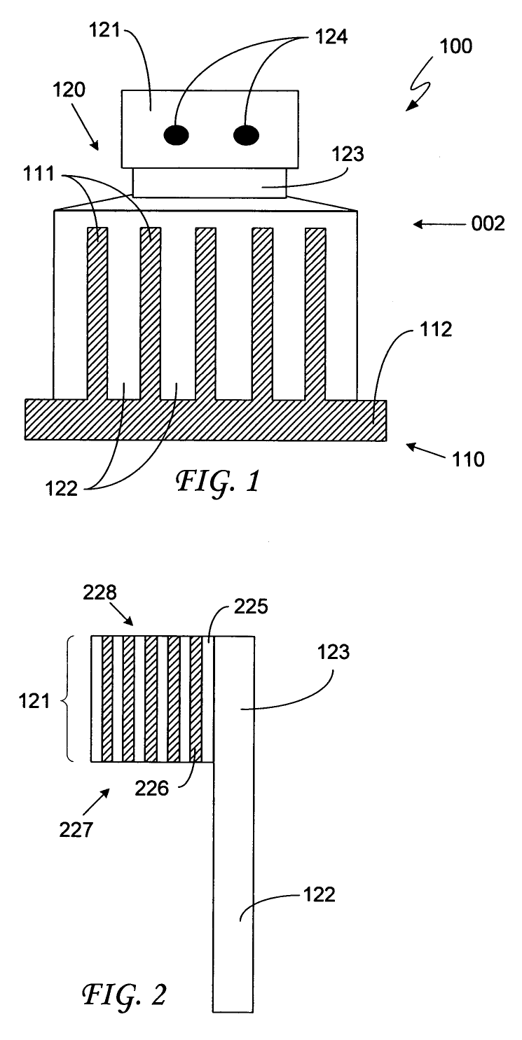

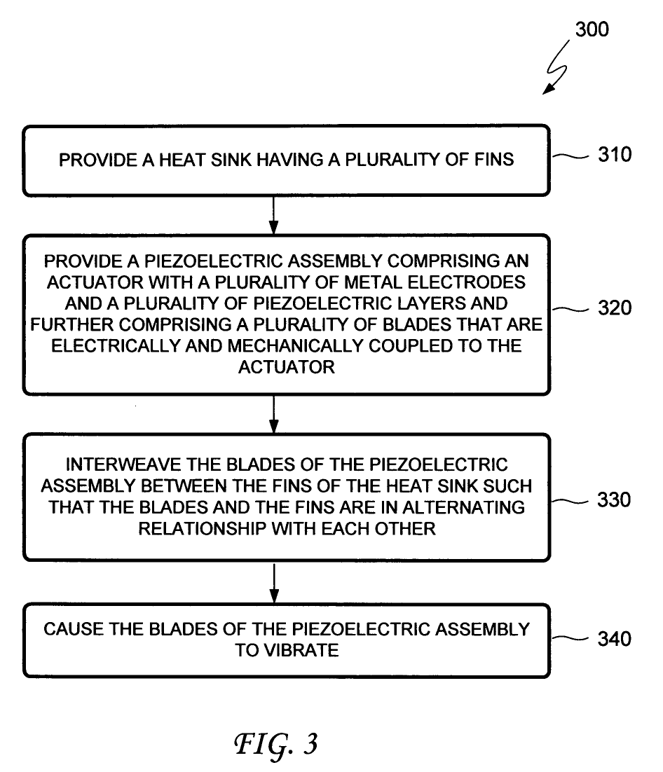

Referring now to the figures, FIG. 1 is a front elevational view of a cooling device 100 according to an embodiment of the invention. FIG. 2 is a side elevational view of a portion of cooling device 100 showing what one would see by looking in the direction indicated by an arrow 002 in FIG. 1 if the heat sink were removed. As illustrated in FIGS. 1 and 2, cooling device 100 comprises a heat sink 110 having a plurality of fins 111 and a base 112. Cooling device 100 further comprises a piezoelectric assembly 120 comprising an actuator 121 and a plurality of blades 122 electrically and mechanically coupled to actuator 121. Plurality of blades 122 feed into a neck 123, which is adjacent to actuator 121. Actuator 121 comprises a plurality 227 of metal electrodes, including a metal electrode 225 that is exemplary of plurality 227, and further comprises a plurality 228 of piezoelectric layers, including a piezoelectric layer 226 that is exemplary of plurality 228. Holes 124 are for the purpose of attaching cooling device 100 to some retention mechanism (not shown).

As an example, plurality of blades 122 can be made of plastic, steel, or the like. As another example, metal electrode 225 can be made of a highly electrically conductive material such as nickel, silver palladium, or the like. In one embodiment, metal electrode 225 has a thickness of between approximately three and approximately eight micrometers. In the same or another embodiment, actuator 121 comprises at least three metal electrodes, one of which may be metal electrode 225. In general, performance increases with the number of layers making up actuator 121. Care must be taken, however, to keep the total number of layers (including metal electrode layers and piezoelectric layers) small enough that the stiffness of actuator 121 does not become too great.

As another example, piezoelectric layer 226 can be made of lead zirconium titanate (PZT) or a lead-free piezoelectric material such as bismuth titanate or the like. Alternatively, piezoelectric layer 226 can be made of another piezoelectric material, including piezoelectric polymers. In one embodiment, piezoelectric layer 226 has a thickness no greater than approximately 30 micrometers. In the same or another embodiment, actuator 121 comprises at least two piezoelectric layers, one of which may be piezoelectric layer 226.

As an example, each metal electrode in plurality 227 of metal electrodes can be similar to metal electrode 225. As another example, each piezoelectric layer in plurality 228 of piezoelectric layers can be similar to piezoelectric layer 226. Plurality 227 of metal electrodes and plurality 228 of piezoelectric layers are in alternating relationship with each other as shown. In the illustrated embodiment, metal electrode 225 is immediately adjacent to neck 123 and the outermost layer (farthest from neck 123) is another metal electrode such that each piezoelectric layer in plurality 228 of piezoelectric layers lies between two metal electrodes.

Governed by what may be called the reverse piezoelectric effect, piezoelectric material undergoes a small change in length when it is subjected to an externally applied voltage. If the applied voltage takes the form of an alternating current then the piezoelectric material can be caused to cycle rapidly between relaxed and constricted states and, as known in the art, this provides a way to induce a lateral vibration in a blade or other object attached to the piezoelectric material. This concept may be put to use with cooling device 100 by applying an alternating current to piezoelectric layer 226 in order to cause a simultaneous lateral vibration of blades 122. By electrically connecting each one of plurality 228 of piezoelectric layers to each other in parallel, such lateral vibration may be achieved at much lower voltages than are possible with single-layer piezoelectric actuators, as will be further discussed below.

In the illustrated embodiment, plurality of blades 122 are inserted substantially all the way into spaces defined by and located between adjacent ones of plurality of fins 111 such that approximately one hundred percent of each one of plurality of blades 122 overlaps with at least one of the plurality of fins 111. In a non-illustrated embodiment, less than approximately one hundred percent but at least approximately ten percent of each one of plurality of blades 122 overlaps with at least one of the plurality of fins of the heat sink. In other embodiments the overlap may be even less than ten percent. In certain embodiments of the invention, the lesser overlap percentage may result in performance gains for cooling device 100, possibly in terms of increased cooling efficiency or the like.

Also in the illustrated embodiment, plurality of blades 122 are arranged so as to be approximately parallel to plurality of fins 111, which fins extend substantially perpendicularly from base 112 of heat sink 110. In a non-illustrated embodiment, plurality of blades 122 lie approximately horizontally to base 112, which may also, in certain embodiments of the invention, result in performance gains for cooling device 100. Other geometries may also be constructed in which plurality of fins 111 lie at other angles with respect to base 112.

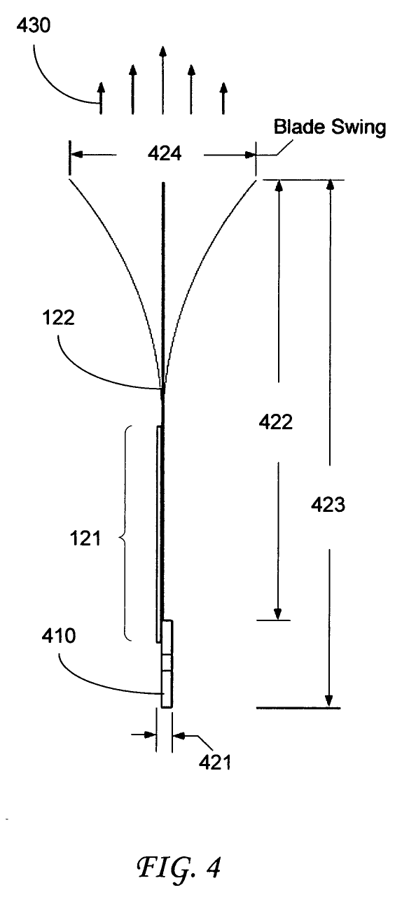

FIG. 3 is a flowchart illustrating a cooling method 300 according to an embodiment of the invention. A step 310 of method 300 is to provide a heat sink having a plurality of fins. As an example, the heat sink can be similar to heat sink 110, first shown in FIG. 1. As another example, the plurality of fins can be similar to plurality of fins 111 that were also first shown in FIG. 1.

A step 320 of method 300 is to provide a piezoelectric assembly comprising an actuator with a plurality of metal electrodes and a plurality of piezoelectric layers and further comprising a plurality of blades that are electrically and mechanically coupled to the actuator. As an example, the piezoelectric assembly, the actuator, and the plurality of blades can be similar to, respectively, piezoelectric assembly 120, actuator 121, and plurality of blades 122, all of which were first shown in FIG. 1. As another example, each one of the plurality of metal electrodes and each one of the plurality of piezoelectric layers can be similar to, respectively, metal electrode 125 and piezoelectric layer 126, both of which were first shown in FIG. 1.

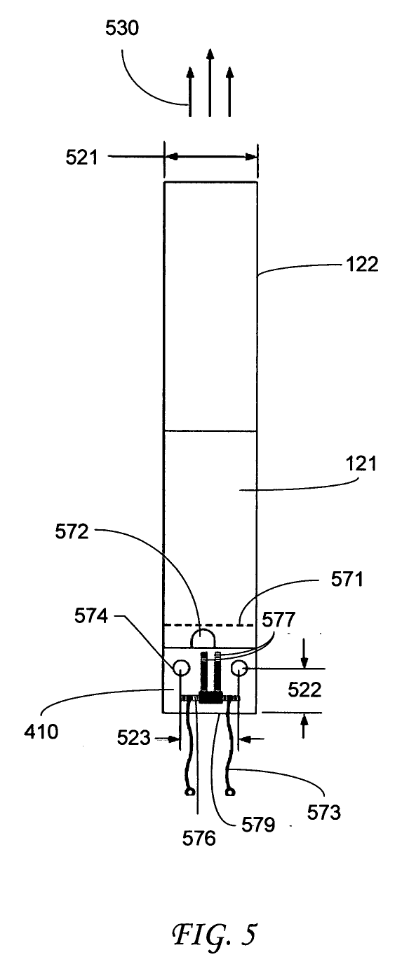

In one embodiment, step 320 comprises providing blades that are approximately 70 millimeters long. In that and possibly other embodiments, an input voltage of no greater than approximately 15 volts is capable of generating a vibration amplitude of at least approximately 40 millimeters. The situation is depicted in FIG. 4, which is a side view of a portion of cooling device 100 showing actuator 121 and one of plurality of blades 122. As illustrated in FIG. 4, blade 122 is attached to actuator 121 that extends from a printed circuit board (PCB) 410. As further illustrated in FIG. 4, PCB 410 has a thickness 421, blade 122 has a length 422, blade 122 and PCB 410 together have a length 423, and the vibration of blade 122 has a peak-to-peak amplitude 424. Such vibration causes airflow in the direction of arrows 430. As mentioned earlier in this paragraph, in one embodiment of the invention an input voltage of just approximately 15 volts is capable of causing peak-to-peak amplitude 424 to be at least approximately 40 millimeters for a length 422 of approximately 70 millimeters.

In the embodiment described immediately above, the blades of the piezoelectric assembly were approximately 70 millimeters long. In some cases, such as those where space is constrained by a small form factor, a 70 millimeter blade may be too long. Embodiments of the invention are able to generate sufficient air flow to perform adequate cooling even where the piezoelectric assembly comprises blades that are no longer than approximately 55 millimeters. Referring again to FIG. 4, in one embodiment length 422 is approximately 55 millimeters and peak-to-peak amplitude 424 is approximately 20 millimeters. In one manifestation of that embodiment, the stated peak-to-peak amplitude is achievable using an input voltage of only approximately five volts, which, advantageously, is well within the available voltage range for most computer systems.

FIG. 5 is a top view of the portion of cooling device 100 shown in FIG. 4 according to an embodiment of the invention. As illustrated in FIG. 5, PCB 410 has an end 571 (shown in dotted lines because it is behind support piece 410) where PCB 410 meets blade 122. A solder area 572 indicates a location where a wire may be attached to an electrode of actuator 121. Wires 573 (and their extensions indicated at 576 and 577) conduct electricity to a first one and a second one of the metal electrodes. Any or all of the wires or wire portions indicated by 573, 576, and 577 can be actual wires or can be electrically conducting channels filled with solder or the like. Aperture 574 (and a matching, unlabeled hole opposite it on the other side of wires 573) extends through PCB 410 and is used to attach the assembly to a retention mechanism (not shown). Aperture 574 and its unlabeled counterpart are separated from each other by a distance 523, and are spaced apart from an end 579 of actuator 121 by a distance 522.

When blade 122 is made to vibrate in accordance with embodiments of the invention, air flow is generated in the direction of arrows 530. As indicated, blade 122 has a width 521. In a particular embodiment, width 521 is between approximately 12 and 13 millimeters, distance 522 is between approximately six and seven millimeters, and distance 523 is between approximately seven and eight millimeters. In the same or another particular embodiment, wires 573 are approximately 150 millimeters long.

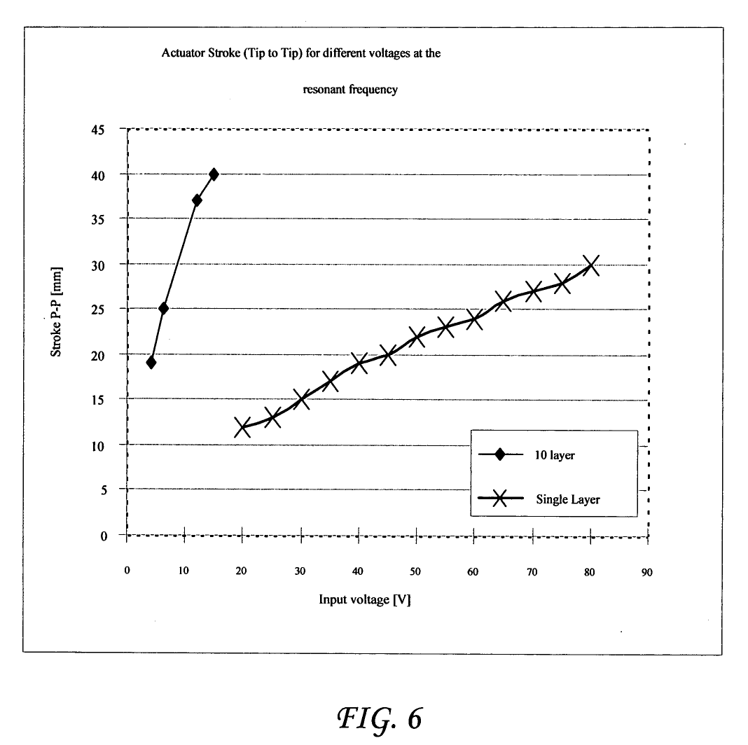

FIG. 6 is a graph plotting peak-to-peak amplitude (in millimeters) of an actuator prong as a function of input voltage for a piezoelectric assembly having a multi-layer actuator according to an embodiment of the invention as well as for a piezoelectric assembly having a single-layer actuator. As illustrated in FIG. 6, the multi-layer (ten-layer, in the illustrated case) actuator achieves a peak-to-peak amplitude of 20 millimeters at an input voltage of approximately 5 volts, while the single-layer actuator achieves a 20 millimeter peak-to-peak amplitude at an input voltage of 45 volts. Similarly, FIG. 6 shows that an input voltage of 80 volts achieves a peak-to-peak amplitude of only approximately 30 millimeters for the single-layer actuator, while a 30-millimeter peak-to-peak amplitude for the multi-layer actuator is achievable with an input voltage of only approximately 10 volts. As these examples, and others apparent from the graph, indicate, a multilayer actuator such as actuator 121 of cooling device 100 may work at lower voltage and better amplitude than a single-layer actuator.

A step 330 of method 300 is to interweave the blades of the piezoelectric assembly between the fins of the heat sink such that the blades and the fins are in alternating relationship with each other. Having this relationship, any air flow generated by the blades will flow around the fins of the heat sink, therefore significantly improving the heat transfer coefficient.

A step 340 of method 300 is to cause the blades of the piezoelectric assembly to vibrate. In one embodiment, step 340 comprises electrically connecting the plurality of piezoelectric layers to each other in parallel and subjecting the plurality of piezoelectric layers to an alternating current. In the same or another embodiment, the performance of step 340 generates air flow that disturbs a boundary layer of air near the plurality of heat sink fins, thus reducing the thermal resistance of the heat sink.

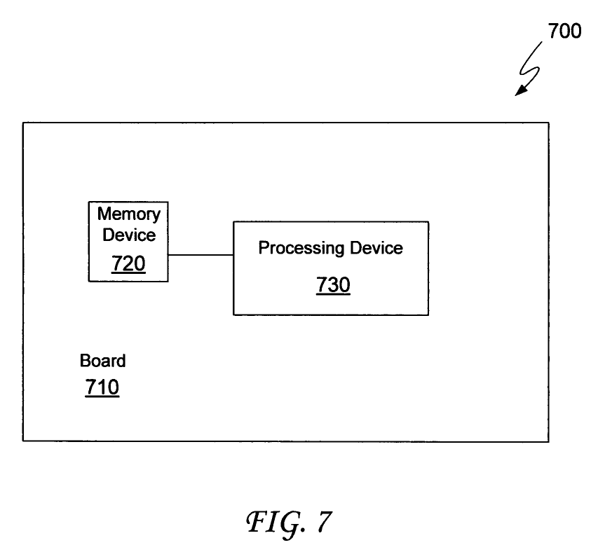

FIG. 7 is a schematic representation of a system 700 according to an embodiment of the invention. As illustrated in FIG. 7, system 700 comprises a board 710, a memory device 720 disposed on board 710, and a processing device 730 disposed on board 710 and coupled to memory device 720. Processing device 730 is contained within a package comprising a heat sink having a plurality of fins and a piezoelectric assembly comprising an actuator having a plurality of metal electrodes and a plurality of piezoelectric layers and a plurality of blades electrically and mechanically coupled to the actuator. The package and its components (other than processing device 730) are not shown in FIG. 7, but the heat sink, the plurality of fins, and the piezoelectric assembly with its components can be similar to, respectively, heat sink 110, plurality of fins 111, and piezoelectric assembly 120 and its components, all of which were described above and are shown at least in FIG. 1. Accordingly, the package can contain a cooling device such as cooling device 100 shown in FIGS. 1 and 2.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the cooling device and related methods and systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A cooling device comprising:
a heat sink having a plurality of fins; and
a piezoelectric assembly comprising:
an actuator having a plurality of metal electrodes and a plurality of piezoelectric layers; and
a plurality of blades electrically and mechanically coupled to the actuator.

2. The cooling device of claim 1 wherein:
the plurality of metal electrodes and the plurality of piezoelectric layers are in alternating relationship with each other.

3. The cooling device of claim 2 wherein:
the plurality of piezoelectric layers are electrically connected to each other in parallel.

4. The cooling device of claim 2 wherein:
the actuator comprises at least three metal electrodes and at least two piezoelectric layers.

5. The cooling device of claim 1 wherein:
each one of the plurality of piezoelectric layers comprises one of lead zirconium titanate and bismuth titanate.

6. The cooling device of claim 5 wherein:
each one of the plurality of piezoelectric layers has a thickness no greater than approximately 30 micrometers.

7. The cooling device of claim 1 wherein:
each one of the plurality of metal electrodes comprises silver palladium.

8. The cooling device of claim 7 wherein:
each one of the plurality of metal electrodes has a thickness of between approximately three and approximately eight micrometers.

9. The cooling device of claim 1 wherein:
no more than approximately ten percent of each one of the plurality of blades overlaps with at least one of the plurality of fins of the heat sink.

10. The cooling device of claim 1 wherein:
the heat sink further comprises a base from which the plurality of fins extend substantially perpendicularly; and
the plurality of blades of the piezoelectric assembly lie approximately horizontally to the heat sink base.

11. A cooling method comprising:
providing a heat sink having a plurality of fins;
providing a piezoelectric assembly comprising:
an actuator having a plurality of metal electrodes and a plurality of piezoelectric layers; and
a plurality of blades electrically and mechanically coupled to the actuator;
interweaving the blades of the piezoelectric assembly between the fins of the heat sink; and
causing the blades of the piezoelectric assembly to vibrate.

12. The cooling method of claim 11 wherein:
causing the blades of the piezoelectric assembly to vibrate comprises:
electrically connecting the plurality of piezoelectric layers to each other in parallel; and
subjecting the plurality of piezoelectric layers to an alternating current.

13. The cooling method of claim 11 wherein:
causing the blades of the piezoelectric assembly to vibrate generates air flow that disturbs a boundary layer of air near the plurality of fins of the heat sink.

14. The cooling method of claim 11 wherein:
providing the piezoelectric assembly comprises providing the plurality of blades to be approximately 70 millimeters long;
a peak-to-peak amplitude of each one of the plurality of blades is at least approximately 40 millimeters; and
an input voltage driving the actuator is no greater than approximately 15 volts.

15. The cooling method of claim 11 wherein:
providing the piezoelectric assembly comprises providing the plurality of blades to be no longer than approximately 55 millimeters; and
a peak-to-peak amplitude of each one of the plurality of blades is at least approximately 20 millimeters.

16. The cooling method of claim 15 wherein:
an input voltage driving the actuator is no greater than approximately five volts.

17. A system comprising:
a board;
a memory device disposed on the board; and
a processing device disposed on the board and coupled to the memory device,
wherein:
the processing device is contained within a package comprising:
a heat sink having a plurality of fins; and
a piezoelectric assembly comprising:
an actuator having a plurality of metal electrodes and a plurality of piezoelectric layers; and
a plurality of blades electrically and mechanically coupled to the actuator.

18. The system of claim 17 wherein:
the plurality of metal electrodes and the plurality of piezoelectric layers are in alternating relationship with each other.

19. The system of claim 18 wherein:
the plurality of piezoelectric layers are electrically connected to each other in parallel; and
the actuator comprises at least three metal electrodes and at least two piezoelectric layers.

20. The system of claim 19 wherein:
each one of the plurality of metal electrodes has a thickness of between approximately three and approximately eight micrometers; and
each one of the plurality of piezoelectric layers has a thickness no greater than approximately 30 micrometers.
